(19) United States
(12) Patent Application Publication
(10) Pub. No.: US 2009/0061619 A1
(43) Pub. Date: Mar. 5, 2009

(54) METHOD OF FABRICATING METAL LINE

(76) Inventor: Sang-Il Hwang, Wonju-si (KR)

Correspondence Address: SHERR & VAUGHN, PLLC, 620 HERNDON PARKWAY, SUITE 200, HERNDON, VA, 20170, US

(21) Appl. No.: 12/197,330

(22) Filed: Aug. 25, 2008

(30) Foreign Application Priority Data
Aug. 31, 2007 (KR) 10-2007-0088258

(51) Int. Cl. H01L 21/768

(52) U.S. Cl. 438/637; 438/700; 257/E21.586

(57) ABSTRACT

A method of fabricating a metal line of a semiconductor device that prevents formation of serrations in a metal line to thereby increase operational reliability of a semiconductor device. The method includes forming a lower metal line in a semiconductor substrate; and then forming a first nitride layer as an etching stop layer over the semiconductor substrate including the lower metal line; and then forming a first insulating layer over the first nitride layer; and then forming a second nitride layer over the first insulating layer; and then forming a contact hole partially exposing the uppermost surface of the lower metal line by performing a first etching process; and then simultaneously forming a second insulating layer over the second nitride layer and a void in the contact hole; and then forming a trench corresponding spatially to the contact hole and partially exposing the uppermost surface of the lower metal line by performing a second etching process.

The present application claims priority under 35 U.S.C. §119 to Korean Patent Application No. 10-2007-0088258 (filed on Aug. 31, 2007), which is hereby incorporated by reference in its entirety.

### BACKGROUND

Manufacturing semiconductor devices may require forming one or more metal lines. A metal line has various functions of connecting circuits, matching circuits, changing a signal phase, etc. A metal line may be formed in a multi-layer structure on and/or over an interlayer insulating layer. Metal lines in respective layers are electrically connected to each other through contacts. Specifically, in a case where a semiconductor device below 130 mu grade is manufactured, an upper metal line may be formed by using a deep ultra-violet (DUV) photoresist instead of a mid ultra-violet (MUV) photoresist in order to satisfy minimized design conditions. However, in a case of a DUV photoresist, serrations are formed on the metal line during etching. Particularly, serrations may be formed due to an etching amount (including etching of a trench for an upper metal line and a contact) is large, the thickness of a DUV photoresist is comparatively small, and the etching resistance of the photoresist is weak.

In an attempt to solve this problem, a method of increasing the etch selectivity between an insulating layer and a photoresist by controlling conditions of an etching process may be employed. However, there is a problem such that the improved etch selectivity makes it difficult to regulate an etching stop position. In other words, while using an improved etch selectivity can settle the problem of serrations on the upper metal line, it causes a problem such that etching is stopped at a middle portion of an insulating layer. Accordingly, a contact for connecting an upper metal line is not formed to a predetermined depth to an underlying layer. Such problems cause a reduction in operational reliability of a semiconductor device, and thus, causes product inferiority.

### SUMMARY

Embodiments relate to a method of fabricating a metal line which prevents serrations

Embodiments relate to a method of fabricating a metal line in which the depth of a trench for a metal line can be accurately controlled.

Embodiments relate to method of fabricating a metal line that may include at least one of the following steps: forming a first insulating layer on and/or over a substrate having a lower metal line; and then forming a nitride layer on and/or over the first insulating layer; and then forming a contact hole by partially etching the first insulating layer and the nitride layer so that a portion of the uppermost surface of the lower metal line is exposed; and then forming a second insulating layer on and/or over the nitride layer so that a void is formed in either an entire or a partial area of the contact hole; and then forming a trench by partially etching the second insulating layer.

Embodiments relate to method of fabricating a metal line that may include at least one of the following steps: forming a lower metal line in a semiconductor substrate; and then forming a first nitride layer as an etching stop layer over the semiconductor substrate including the lower metal line; and then forming a first insulating layer over the first nitride layer; and then forming a second nitride layer over the first insulating layer; and then forming a contact hole partially exposing the uppermost surface of the lower metal line by performing a first etching process; and then simultaneously forming a second insulating layer over the second nitride layer and a void in the contact hole; and then forming a trench corresponding spatially to the contact hole and partially exposing the uppermost surface of the lower metal line by performing a second etching process.

Embodiments relate to method of fabricating a metal line that may include at least one of the following steps: forming a first nitride layer over a semiconductor substrate having a lower metal line; and then forming a first insulating layer over the first nitride layer; and then forming a second nitride layer over the first insulating layer; and then forming a contact hole partially exposing the uppermost surface of the lower metal line by performing a first etching process; and then simultaneously forming a second insulating layer over the second nitride layer and a void in the contact hole; and then forming a trench partially exposing the uppermost surface of the lower metal line by performing a second etching process such that the uppermost surface of the second nitride layer has a stepped-up uppermost surface; and then filling the contact hole and the trench with a metal material to simultaneously form a contact and an upper metal line.

### DRAWINGS

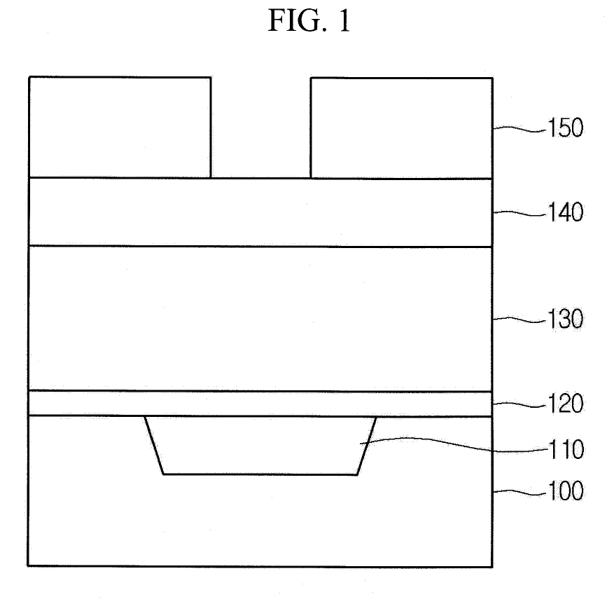

Example FIGS. 1-4 illustrate a method of fabricating a metal line in a semiconductor device in accordance with embodiments.

### DESCRIPTION

A method of fabricating a metal line according to the present invention will be described in detail with reference to the accompanying drawings. Note that a semiconductor device, to which a method of fabricating a metal line according to the present invention is applied, is a micro device below 110 nm grade.

Example FIG. 1 illustrates of a shape after first photoresist pattern 150 of a semiconductor device is formed.

As illustrated in example FIG. 1, lower metal line 110 is formed in substrate 100. Additionally, other lower components, such as a semiconductor layer or other metal lines, may be formed on and/or over substrate 100 below lower metal line 110. Etching stop layer 120 is formed on and/or over substrate 100 including lower metal line 110. First insulating layer 130, which is a region for forming a contact hole, is formed on and/or over etching stop layer 120. Etching stop layer 120 may be made of a material containing silicon nitride (SiN) while first insulating layer 130 may be made of a material containing oxide series or an interlayer metal dielectric (IMD) series. Etching stop layer 120 may be formed to have a thickness of substantially 1000 Å while first insulating layer 130 may be formed to have a thickness of substantially 8000 Å. Nitride layer 140 may then be formed on and/or over first insulating layer 130 to have a thickness of substantially 2000 Å. Nitride layer 140 may be formed of a material containing SiN. First photoresist pattern 150 is then formed on and/or over nitride layer 140. Because the semiconductor device in accordance with embodiments is a micro device below 110 nm grade, it is preferred that first photoresist pattern 150 is formed using a DUV photoresist.

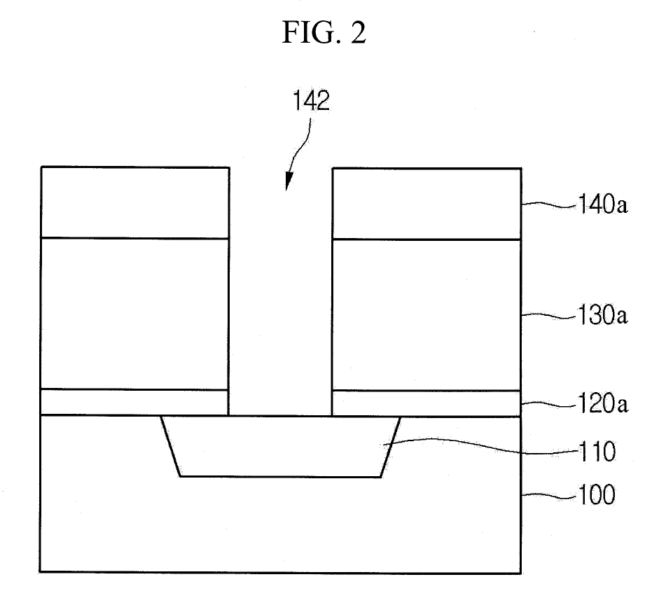

As illustrated in example FIG. 2, contact hole 142 is formed by sequentially partially etching nitride layer 140, first insulating layer 130 and etching stop layer 120 using first photoresist pattern 150 as an etching mask to partially expose an uppermost surface of lower metal line 110. Etching stop layer 120 satisfies etching stop conditions to thereby prevent lower metal line 110 from being etched. After forming contact hole 142, an ashing process and a clean process may then be performed.

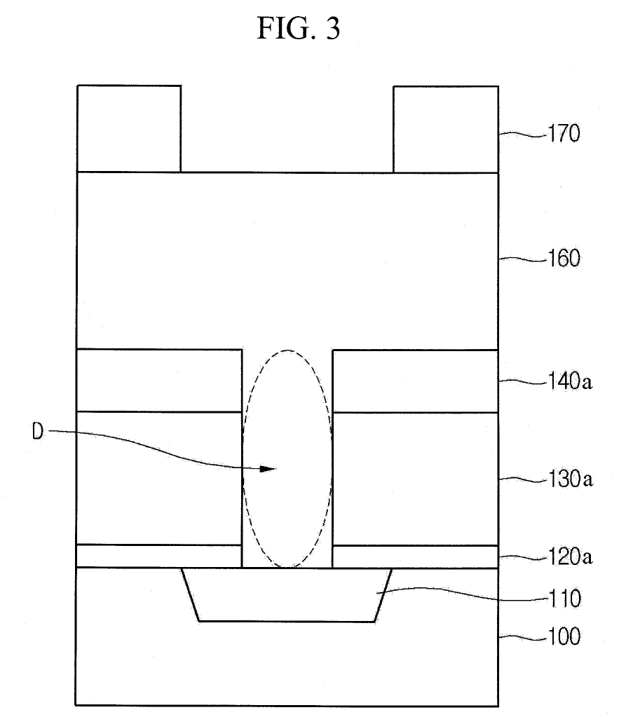

As illustrated in example FIG. 3, after contact hole 142 is formed, second insulating layer 160, which is a region for forming the upper metal line, is formed. Particularly, after the above-described first etching process, an oxide series material or an interlayer metal dielectric (IMD) series material is deposited on and/or over nitride layer 140a to form second insulating layer 160. At this time, void (D) may be formed in a portion of second insulating layer 160 formed in contact hole 142 or fully in contact hole 142 without the presence of second insulating layer 160. Void (D) may be naturally formed in the deposition process of second insulating layer 160 without an additional process for injecting air into contact hole 142. In a case where the contact hole is filled up, a filler is injected little by little while securing an exhaust channel through which air can be exhausted. In accordance with embodiments, void (D) can be formed in contact hole 142 by depositing a large amount of IMD so as to block an air exhaust channel, and controlling deposition conditions such as an injection direction of a filler material. Therefore, contact hole 142 is not filled up with second insulating layer 160, or a small portion of second insulating layer 160 may be formed in contact hole 142. Subsequently, second photoresist pattern 170 is formed on and/or over second insulating layer 160. Similar to first photoresist pattern 150, second photoresist pattern 170 may be formed by using a DUV photoresist.

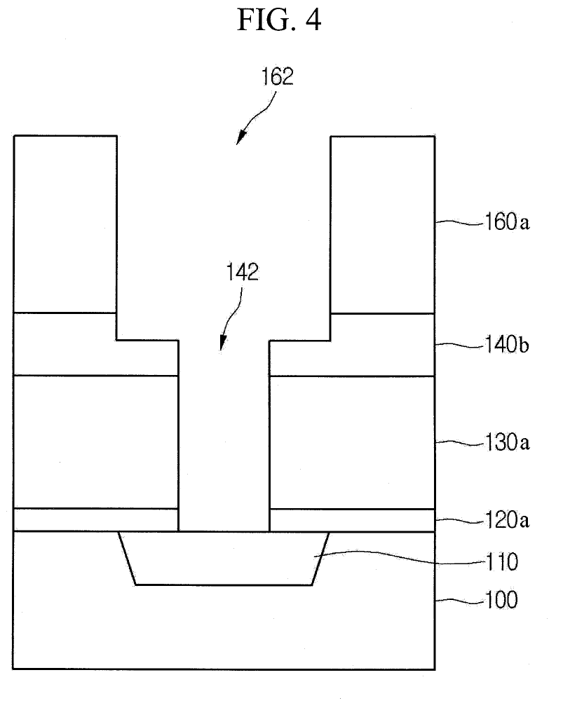

As illustrated in example FIG. 4, trench 162 is then formed by performing a second etching process etching second insulating layer 160 using second photoresist pattern 170 as an etching mask. At the same time, contact hole 142 formed with void (D) is also subjected to etching. Accordingly, even a small amount of material of second insulating layer 160, which may exist in contact hole 142, can be totally removed. Also, when second insulating layer 160 is etched, nitride layer 140a after the first etching functions as a self-alignment mask in order to efficiently control the etching region. Accordingly, an uppermost surface of nitride layer 140a is partially etched to form nitride layer 140b having a stepped uppermost surface. In the etching process for forming trench 162, by applying the etching process to the inside of contact hole 142 using nitride layer 140a as a self-alignment mask, trench 162 can be formed to be extended to a portion of the uppermost surface of nitride layer 140b while contact hole 142 can keep its original shape. Thereafter, an ashing process and a cleaning process for trench 162 and contact hole 142 are performed to remove foreign substances, debris and matter therefrom. Contact hole 142 and trench 162 may then be filled with a metal material to thereby complete a fabricating process of a contact and an upper metal line.

In accordance with embodiments, the contact hole for the contact and the trench for the upper metal line are not etched simultaneously, but are formed in a sequence of steps. Because a void is formed in contact hole 142, an object to be etched in the second etching process is restricted to second insulating layer 160. Therefore, because a burden of an etching amount is remarkably reduced, the etching conditions can be easily controlled, and a sufficient process margin can be secured even though a photoresist having a comparatively small thickness is used. Furthermore, the accurate profiles of the contact and the upper metal line can be obtained, and occurrence of defect on the metal line can be prevented.

Accordingly, in accordance with embodiments, occurrence of serrations in a metal line is prevented, thereby increasing operational reliability of a semiconductor device. Secondly, a process margin of a photoresist thickness can be secured by reducing an etching amount of an etched layer. Therefore, occurrence of serrations in the metal line is prevented and a contact having accurate dimensions can be formed.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a first insulating layer over a substrate having a lower metal line; and then
forming a nitride layer over the first insulating layer; and then
forming a contact hole by performing a first etching process partially etching the first insulating layer and the nitride layer to expose a portion of the uppermost surface of the lower metal line; and then
simultaneously forming a second insulating layer over the nitride layer and a void in the contact hole; and then
forming a trench by performing a second etching process partially etching the second insulating layer.

2. The method of claim 1, wherein forming the first insulating layer comprises:
forming an etching stop layer on the substrate including the lower metal line; and then
forming the first insulating layer on the etching prevention layer.

3. The method of claim 1, wherein forming the contact hole comprises:
forming a first photoresist pattern on the nitride layer; and then
performing the first etching process on the first insulating layer and the nitride layer using the first photoresist pattern as an etching mask.

4. The method of claim 3, further comprising, after performing the first etching process:
performing at least one of an ashing process, and a cleaning process on the contact hole.

5. The method of claim 3, wherein the first photoresist pattern is formed by a DUV photoresist.

6. The method of claim 1, wherein forming the trench comprises:
forming a second photoresist pattern on the second insulating layer; and then
performing the second etching process using the second photoresist pattern as an etching mask.

7. The method of claim 6, wherein performing the second etching process comprises performing the second etching process on the contact hole using the nitride layer as a self-alignment mask.

8. The method of claim 6, further comprising, after performing the second etching process:
performing at least one of an ashing process and a cleaning process on the trench and the contact hole.

9. The method of claim 6, wherein the second photoresist pattern is formed by a DUV photoresist.

10. The method of claim 1, wherein the first insulating layer comprises an interlayer metal dielectric (IMD) material.

11. The method of claim 1, wherein the second insulating layer comprises an interlayer metal dielectric (IMD) material.

12. The method of claim 1, wherein the nitride layer comprises SiN.

13. The method of claim 1, wherein the trench is formed to be extended to a portion of the uppermost surface of the nitride layer.

14. The method of claim 1, further comprising, after forming the trench:
filling the trench and the contact hole with a metal material.

15. A method comprising:
forming a lower metal line in a semiconductor substrate; and then
forming a first nitride layer as an etching stop layer over the semiconductor substrate including the lower metal line; and then
forming a first insulating layer over the first nitride layer; and then
forming a second nitride layer over the first insulating layer; and then
forming a contact hole partially exposing the uppermost surface of the lower metal line by performing a first etching process; and then
simultaneously forming a second insulating layer over the second nitride layer and a void in the contact hole; and then
forming a trench corresponding spatially to the contact hole and partially exposing the uppermost surface of the lower metal line by performing a second etching process.

16. The method of claim 15, wherein the first nitride layer and the second nitride layer comprises a silicon nitride material.

17. The method of claim 15, wherein simultaneously forming the second insulating layer and the void comprises:
forming the void in at least one of a portion of the second insulating layer formed in the contact hole and fully in the contact hole without the presence of the second insulating layer.

18. The method of claim 15, wherein during the second etching the uppermost surface of the second nitride layer is partially etched to form a stepped uppermost surface thereof.

19. The method of claim 15, further comprising, after forming the trench:
simultaneously forming a contact in the contact hole and an upper metal line in the trench.

20. A method comprising:
forming a first nitride layer over a semiconductor substrate having a lower metal line; and then
forming a first insulating layer over the first nitride layer; and then
forming a second nitride layer over the first insulating layer; and then
forming a contact hole partially exposing the uppermost surface of the lower metal line by performing a first etching process; and then
simultaneously forming a second insulating layer over the second nitride layer and a void in the contact hole; and then
forming a trench partially exposing the uppermost surface of the lower metal line by performing a second etching process such that the uppermost surface of the second nitride layer has a stepped-up uppermost surface; and then
filling the contact hole and the trench with a metal material to simultaneously form a contact and an upper metal line.
